(19) United States
(12) Patent Application Publication
(10) Pub. No.: US 2025/0320931 A1
(43) Pub. Date: Oct. 16, 2025

(54) PNEUMATIC VALVE

(71) Applicant: Conti Temic microelectronic GmbH, Ingolstadt (DE)

(72) Inventors: Michael Beuschel, Stammham (DE); Stefan Bauer, Engelbrechtsmünster (DE); Johann Steinberger, Brunnen (DE); Jürgen Wedell, Rastatt (DE)

(21) Appl. No.: 19/176,316

(22) Filed: Apr. 11, 2025

(30) Foreign Application Priority Data
Apr. 12, 2024 (DE) 10 2024 203 381.2

(51) Int. Cl. F16K 31/02; F16K 11/048

(52) U.S. Cl. CPC F16K 31/02; F16K 11/048

(57) ABSTRACT

A pneumatic valve comprises a housing with a valve chamber having a first opening connecting to a first gas port, a second opening connecting to a second gas port, and a third opening connecting to an actuator chamber connected to a third gas port, and an SMA actuator with a movable closing element. The closing element has a plunger protruding through the third opening and projecting into the valve chamber, a sealing plate with a first sealing element for closing the first opening and a second sealing element for closing the third opening. A spring element pushing the second sealing element in the direction of the third opening when the pneumatic valve is activated connects to the closing element. The plunger and the actuator, via a driver element, have a form-fitting connection with play such that actuation of the actuator causes the plunger to move within the play.

### BRIEF DESCRIPTION OF THE DRAWINGS

The disclosure is described in more detail below on the basis of exemplary embodiments with the aid of figures, in which:

FIG. 1 shows a first exemplary embodiment variant of a pneumatic valve in an unactuated state;

FIG. 2 shows the first exemplary embodiment variant of the valve in the actuated state during a filling operation;

FIG. 3 shows a detailed view of an exemplary pneumatic valve in an unactuated state;

FIG. 4 shows a detailed view of the first exemplary embodiment variant of the valve in an actuated intermediate state;

FIG. 5 shows a detailed view of the first exemplary embodiment variant of the valve in the open end state;

FIG. 6 shows a detailed view of a second exemplary embodiment variant of a pneumatic valve in an unactuated state;

FIG. 7 shows a detailed view of the second exemplary embodiment variant of the valve in an actuated intermediate state;

FIG. 8 shows a detailed view of the second exemplary embodiment variant of the valve in the open end state;

FIG. 9 shows a detailed view of a third exemplary embodiment variant of a pneumatic valve in an unactuated state;

FIG. 10 shows a detailed view of the third exemplary embodiment variant of the valve in an actuated intermediate state;

FIG. 11 shows a detailed view of the third exemplary embodiment variant of the valve in the open end state.

### DETAILED DESCRIPTION

The disclosure relates to a pneumatic valve, having a housing in which a valve chamber is arranged with a first opening for connecting to a first housing gas port, a second opening for connecting to a second housing gas port and with a third opening for connecting the valve chamber to an actuator chamber, which is connected to a third housing gas port, wherein an SMA actuator with a movable closing element is arranged in the housing, wherein the closing element is formed with a plunger which protrudes through the third opening and, at its end projecting into the valve chamber, a plate is formed at which a first sealing element for closing the first opening and a second sealing element for closing the third opening are arranged, wherein a spring element pushing the second sealing element in the direction of the third opening in the activated state of the pneumatic valve is operatively connected to the closing element.

Such a pneumatic valve is known from DE 10 2018 216 874 A1 and also from DE 10 2019 208 051 A1. In these valves, the first opening of the valve chamber is closed by the first sealing element in the unactuated state of the actuator. In the actuated state of the actuator, the plunger is intended to be pushed by the force of the spring element away from the first opening to the third opening, as a result of which the latter is closed by the second sealing element. The first and the second sealing element can be formed integrally from a soft material and connected to the plunger, which is formed from a harder material. However, they can also be provided on a plate which is formed at that end of the plunger which is located in the valve chamber.

Such pneumatic valves are used, e.g. in means of transport, for shaping seat contours by fillable, elastic cushions. For this purpose, the elastic cushions are usually filled with air as the gas. The electrically actuatable pneumatic valves are used for controlling the supply of air. For the function of a static contour adjustment, a long retaining period (hours to days) is required and therefore exacting requirements are imposed on the tightness of the associated pneumatic valves.

If a valve remains in the closed position for a long period, even changing ambient influences, such as temperature changes, may result in increased adhesion (sticking) of a sealing element to the nozzle seat. When the valve is subsequently activated, said sealing element, under some circumstances, may not be detached or may not be detached in the designated time by an elastic element (e.g. inner spring) assisting the opening. In addition, an additional force may be required for opening the valve if the valve is intended to be opened counter to a pressure difference at certain working points.

The increasingly used shape memory alloy (SMA) actuators have only small force reserves, in particular when actuated multiple times. If an opening-assisting inner spring, as is disclosed in the documents mentioned, is used with sufficient force on the sealing element, said force has to be additionally applied during each actuation of the valve by the SMA actuator. This reduces its service life. By contrast, a higher force to be applied sporadically (e.g. only for actuation for the first time after a relatively long retaining period) appears to be justifiable in respect of the effect on the service life of the SMA actuator.

DE 10 2018 112 090 A1 describes an SMA actuator which is used in such a way that it can exert an increased opening force on the sealing element when required by the sealing element being actively pulled away from the nozzle seat. For this purpose, however, the SMA actuator has to be located in the pressure chamber of the valve.

DE 10 2017 213 744 B3 discloses a pneumatic valve in which the sealing element is moved by a rotational movement. The detaching from the nozzle seat is thus assisted by a peeling movement.

DE 10 2022 207 882 A1 describes an integrated nonreturn valve which, with assistance by the admission pressure, can be opened counter to a strong restoring spring.

DE 10 2023 203 271 A1 describes a valve arrangement in which a 3/3-way valve is represented by interconnected 3/2- and 2/2-way valves. In this case, the SMA actuator is located in the pressure-less chamber (e.g. ambient pressure).

DE 10 2022 202 438 A1 and DE 10 2016 219 342 A1 both disclose pneumatic valves with an SMA wire actuator.

DE 10 2016 112 115 A1 discloses a valve linear drive for connection to a valve body having a valve seat, with a form-fitting connection with play between the driver element and pulling component.

It is the object of the disclosure to specify a valve with an SMA actuator in ambient pressure, in which the opening can be actively assisted by the actuator. Optionally, this additional force is intended to be limited in order to protect the actuator.

The object is achieved with a pneumatic valve of the type in question in that the plunger and the actuator, via a driver element, have a form-fitting connection with play such that actuation of the actuator causes the plunger to be moved by the actuator to the extent of the play.

The actuator arrangement is therefore configured in such a manner that it can exert both a compressive force and a pulling force on the plunger in order either to close the first opening or to assist removal of the first sealing element from the first opening. However, because of the play of the driver element, the force of the actuator is only used if the first sealing element is poorly released from its sealing seat on the first opening, and therefore an existing spring force is not sufficient for this purpose.

In an embodiment of the pneumatic valve, the actuator further comprises: a printed circuit board arranged in the actuator chamber, an actuating element which is arranged in the actuator chamber and has an actuating portion for acting on the plunger, and a bending portion connected to the actuating portion and to the printed circuit board, and an actuator element which is arranged in the actuator chamber and has a first end mechanically connected to the actuating portion and a second end mechanically and electrically connected to the printed circuit board, wherein the actuator element, in a non-energized state, is designed to bring the actuating element into a first state, in which it pushes the plunger against the first opening, and, in an energized state, to bring the actuating element into a second state, in which the actuating portion does not exert any pushing force on the plunger, and therefore, owing to the action of the driver element and the spring element, the second sealing element is pulled or pushed in the direction of the third opening.

When the SMA actuator is actuated, e.g. the actuator element is energized, the latter is shortened such that the actuating portion of the actuating element is pulled away from the plunger and no longer exerts a direct force on the latter. Owing to the spring force of the spring element, the plunger would then push or pull the first sealing element, which is fastened to said spring element, away from the first opening and would push or pull the second sealing element toward the third opening. However, if the first sealing element sticks to the sealing seat of the first opening, the driver element, after overcoming the play, engages on the plunger and additionally to the spring force pulls the sealing element away from the first opening. The spring element subsequently takes over the plunger movement again and the actuating element no longer exerts any force on the plunger.

In an advantageous embodiment of the pneumatic valve, the spring element is formed by a spiral spring in or outside the valve chamber, which spiral spring is supported on the housing part or on the end part and pushes the plunger from the second opening to the third opening.

In principle, any other suitable spring may also be used, but a spiral spring is of advantage because of the generally concentric design of the valve chamber.

In an alternative embodiment of the pneumatic valve, the spring element is formed by a leaf spring which is formed on the actuating portion of the actuator and which also acts as the driver element.

By this, the force of the driver element can be adjusted by way of the spring constant, and therefore only in the event of a maximum deflection of the leaf spring does a maximum force act which is reduced again when the plunger or sealing element moves.

In an advantageous way, the driver element is connected fixedly to the actuating portion of the actuator and movably to the plunger in such a manner that it is carried along with the actuating portion when the actuator is actuated and, after reaching the end of the play, carries along the plunger.

In this case, the driver element can be rod-shaped and can be guided into recesses of the actuating portion and of a plunger portion and, at its ends, has widened portions which are larger than the cross section of the recesses.

By this, the driver element is firstly movable, but is obstructed in its movement from sliding through the recesses by the widened portion, and therefore, on reaching the end of the play, it can exert its effect and consequently a tensile force on the plunger.

Alternatively, the driver element may also be connected fixedly to, e.g., the actuating portion of the actuator.

This can be of advantage in terms of production and also prevents loss of the driver element.

The driver element can also be connected fixedly to the spring element arranged outside the valve chamber, which advantageously reduces the number of individual parts.

The driver element can have a resilient portion, as a result of which, when the actuator is actuated, a variable force is exerted on the plunger.

The actuator arrangement is therefore designed in such a way that it can exert both a compressive force downward and a tensile force upward on the plunger. The actuator arrangement can be formed integrally or else as an assembled component.

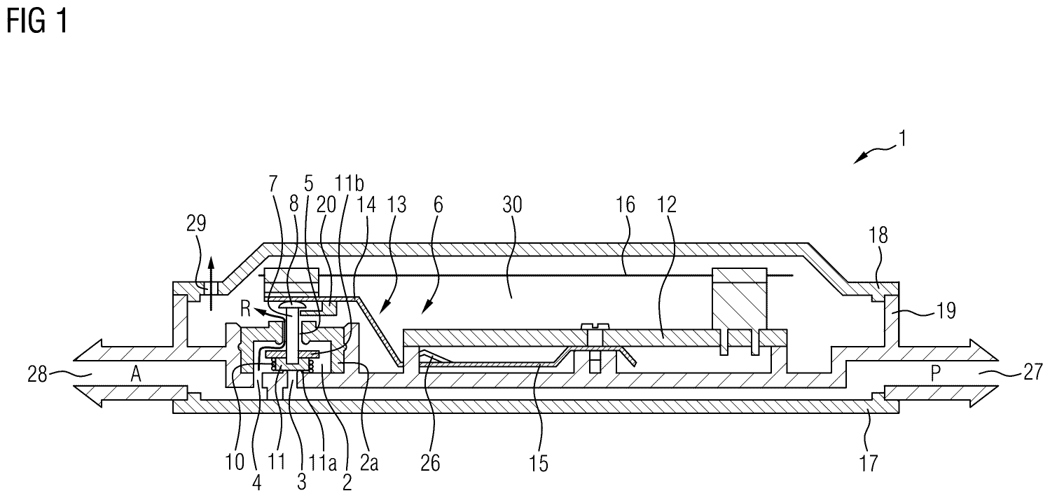

FIG. 1 shows a cross-sectional illustration of a pneumatic valve, which is formed with a housing 1 which has a first housing part 17 in the form of a base plate in the illustrated exemplary embodiment. The housing 1 also has a second housing part 18 which is in the form of a cover, and lastly a third cup-shaped housing part 19 which is in the form of an insert part between the first and the second housing part 17, 18 and on which a supply port 27 and a connecting port 28 are integrally formed. An actuator chamber 30 in which an actuator 6 is installed is formed between the third housing part 19 and the second housing part 18.

A valve chamber 2 is formed on the third housing part 19 by said housing part having a pot-shaped molding into which an end part 2a is inserted as a cover of the valve chamber 2. The connection between the pot-shaped molding and the end part 2a is performed for example, by a press fit or a seal. It can be advantageous for compressive and sealing forces to be absorbed by clips, screws, etc.

The valve chamber 2 has a first opening 3, a second opening 4 and a third opening 5. In the illustrated exemplary embodiment, the first opening 3 and the second opening 4 are formed in the third housing part 19, and the third opening 5 is formed in the end part 2a terminating the valve chamber 2. It is thus possible for a gas, for example compressed air, to be routed, for example from a compressor, via the supply port 27 into the housing 1, wherein the compressed air can pass via the first opening 3 into the valve chamber 2 and from there via the second opening 4 and the connecting port 28 into an air cushion connectable thereto. On the other hand, compressed air from the air cushion can reach the valve chamber 2 via the connecting port 28 and the second opening 4, and from there back to the supply opening, and be discharged if there is no higher pressure prevalent at the latter.

If the pneumatic valve is not actuated, compressed air can pass from an air cushion, which is connected to the connecting port 28, via the connecting port 28 and the second opening 4 into the valve chamber 2 and from there via the third opening 5 into the actuator chamber 30. In the second housing part 18, an outlet opening 29 for connection to, for example, the ambient air is formed, via which outlet opening the air can then pass from the air cushion into the surroundings.

A closing element is formed in the valve chamber 2 with a plunger 7 and, at its end projecting into the valve chamber 2, a sealing plate 11 is arranged or is integrally formed thereon. On the sealing plate 11, a first sealing element 11a is arranged, e.g. integrally formed or bonded or fastened in some other way, on the side facing the first opening 3, and a second sealing element 11b is arranged, e.g. integrally formed or bonded or fastened in some other way, on the side facing the third opening 5. The sealing plate 11 together with the sealing elements 11a, 11b can be composed of a softer material than the plunger 7.

At the end of the plunger 7 protruding out of the valve chamber there is formed a widened portion 8 which, by its overlap over the plunger pin, forms an engagement point for a driver element 20.

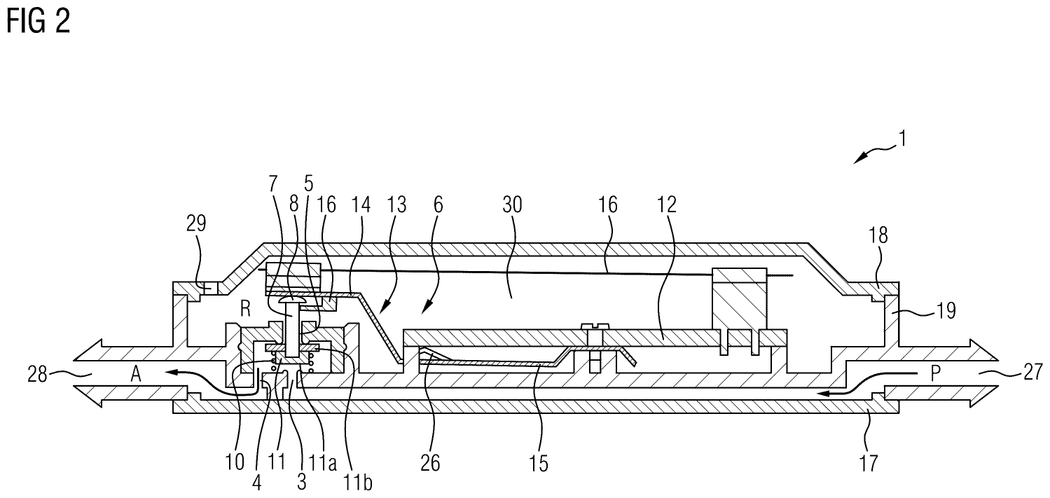

In the exemplary embodiment illustrated in FIGS. 1 and 2, a spring element 10, for example in the form of a spiral spring, is arranged in the valve chamber 2. The spring element 10 is supported at its one end in the region of the first opening 3 on the wall of the valve chamber 2 and at its other end on the sealing plate 11. When the valve is activated, the spring element 10 is intended to push the sealing plate 11 away from the first opening 3 and consequently to open the latter. In the end state, the spring element 10 pushes the second sealing element 11b against the third opening 5 and seals the latter.

Moreover, an actuator 6 is arranged in the housing 1. The actuator 6 is formed with a printed circuit board 12 which is mounted on and mechanically connected to corresponding struts of the third housing part 19. Connected to the printed circuit board 12 is an actuating element 13 which has an actuating portion 14 which is in direct contact with the plunger 7 and has a bending portion 15 connected to the printed circuit board 12.

The actuator 6 also has an actuator element 16, which is preferably formed with a wire that is composed of a shape memory alloy and contracts when current supplied by a circuit (not illustrated) on the printed circuit board 12 is applied thereto. In the non-activated state, the actuating element 13 is preloaded in such a way that the actuating element 13 pushes by way of its actuating portion 14 against the plunger 7, and thus pushes the sealing plate 11 and the first sealing element 11a, which is optionally attached thereto, onto the first opening 3 counter to the force of the spring element 10.

The actuator element 16 is connected both to the actuating element 13 and to the printed circuit board 12—for example by crimp connections.

Advantageously, the actuator element 16 is formed above an upper side of the printed circuit board 12 and the actuating element 13 is formed below a lower side of the printed circuit board 12, such that a very compact construction results. In principle, the structure can also be mirror-inverted, such that the actuator element 16 comes to lie below the printed circuit board 12 and the actuating element 13 comes to lie above the printed circuit board 12.

Advantageously, an end position detection element 26 is formed on the actuating element 13, said end position detection element coming into contact with the printed circuit board 12 when the actuator 6 is actuated and enabling a current flow, as a result of which it is detected that the end position has been reached, with the result that the current can be switched off or at least reduced by the actuator element 16 in order not to overload the latter.

The pneumatic valve has the driver element 20 which, in the exemplary embodiment of FIGS. 1 and 2, is connected fixedly to the actuating portion 14 of the actuating element 13, for example is integrally formed in or on the latter. However, it can also be adhesively bonded, soldered or welded. Other suitable connecting methods are possible.

The upper end of the plunger 7 has a widened portion 8 or a recess, preferably as part of a hard component. The driver element 20 can engage in a form-fitting manner from below on said widened portion 8 and can thus exert a tensile force on the plunger 7. Alternatively, the plunger 7 can also have a corresponding notch on which the driver element 20 can engage. The lower end of the plunger 7 contains the sealing elements 11a, 11b and preferably consists of a soft component.

In FIG. 2, the valve of FIG. 1 is shown in a second, activated state, thus in a state in which the first opening 3 is open and air can flow from the supply port 27 via the connecting port 28 through the valve chamber 2 into a connected air cushion.

In FIG. 2 and in all further Figs., identical parts are provided with the same reference signs as in FIG. 1, with not all of the reference signs always being shown for reasons of clarity.

Activation of the actuator 6 causes the actuating element 13 to be raised and therefore the plunger 7 will likewise be pushed upward by the spring force of the spring element 10. The first sealing element 11a then no longer pushes onto the first opening 3, and therefore the latter is open.

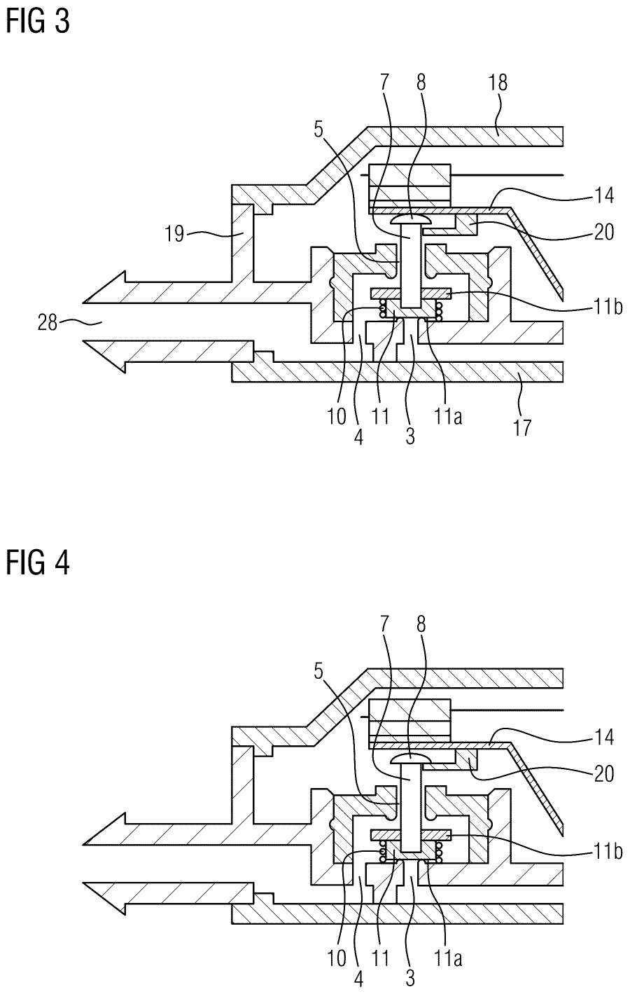

FIGS. 3 to 5 show detailed views of the illustrations of the pneumatic valve of FIGS. 1 and 2. The states shown in FIGS. 3 and 5 correspond to those of FIGS. 1 and 2, respectively. The state of FIG. 4 is an intermediate state in the actuated state, in which, however, the first opening 3 is not yet open because of a sticking first sealing element 11a, since the spring force of the spring element 10 does not suffice to overcome said sticking.

In the inoperative retaining state of FIGS. 1 and 3, the plunger 7 is pushed by the restoring force of the actuator 6 onto the lower nozzle seat of the first opening and therefore seals the latter. The force of the spring element 10 in the valve chamber 2 is substantially smaller than the restoring force of the actuator 6. In this state, because of the play, the driver element 20 does not have any contact with the widened portion 8 of the plunger.

At the beginning of the opening process (see FIG. 4), the first sealing element 11a can be prevented from opening by adhesion or by a positive pressure difference between the valve chamber 2 and the supply port 27. In this case, the actuating portion 14 of the actuator 6 is initially raised to an extent such that the driver element 20 makes contact with the widened portion 8 of the plunger 7 from below and exerts an upwardly directed force on the plunger 7 in order to release the first sealing element 11a from the nozzle seat of the first opening 3.

As soon as the sealing plate 11 with the first sealing element 11a has been released from the lower nozzle seat (FIG. 5), it is moved by the spring element 10 (e.g. spiral spring) to its upper position and is held there by the spring element 10 and possibly by the pressure in the valve chamber 2. Therefore, the valve is open and at the same time the third opening 5 is sealed by the second sealing element 11b. The actuating portion 14 of the actuator 6 then moves further as far as its upper end position such that said actuating portion and the driver element 20 are no longer in contact with the plunger 7 in both directions because of the play and thus also no longer exert any force on the plunger 7.

As already explained, the driver element 20 can be integrally formed both in one piece on an actuator part (e.g. as a tab of an injection molded part or punched and bent part), but can also be mounted in multiple parts, as an additional component, e.g. as a clip, which can come into contact with the plunger 7 from below and the corresponding actuator part from above and is fastened captively to one of said two components.

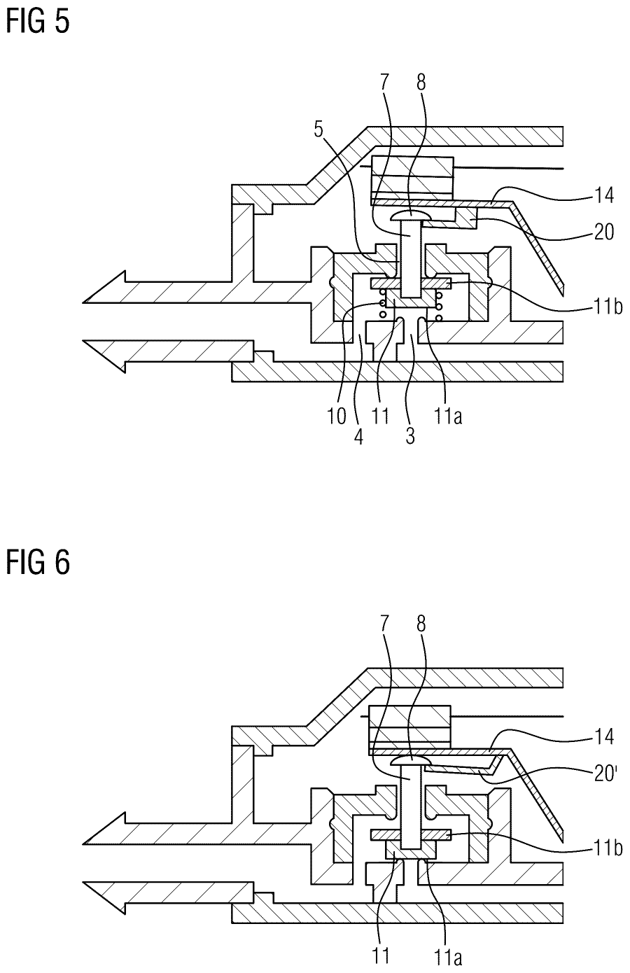

A detailed view of a second embodiment of a pneumatic valve according to the disclosure is shown in each of FIGS. 6 to 8. Here too, identical parts are provided with the same reference signs. The same actuating states as in FIGS. 3 to 5 are shown.

The configuration shown makes it possible to additionally structurally limit the force to be applied by the actuator 6 to a maximally permissible value. This can be required if the valve as a result of environmental conditions or a malfunction requires an excessive force to open it, or opening does not take place in the designated actuating time of the SMA actuator 6. Both may lead to overloading of the SMA actuator 6 and thus to its premature failure.

The driver element 20′ is configured here as a spring element in the form of a leaf spring, which yields at an excessive tensile force. Therefore, the SMA actuator 6 can move further into its end position if the plunger 7 cannot release the first sealing element 11a from the lower nozzle seat at the first opening 3. In addition, this configuration makes it possible to be able to dispense with an inner spring in the valve chamber 2.

In the inoperative retaining state (FIG. 6), the plunger pushes the first sealing element 11a by the restoring force of the actuator 6 onto the lower nozzle seat of the first opening 3 and therefore seals the latter. In the process, the entire restoring force of the actuator 5 acts on the plunger 7 in order to apply the sealing force for the lower nozzle seat (e.g., the restoring force is not reduced by the oppositely acting force of an inner spring).

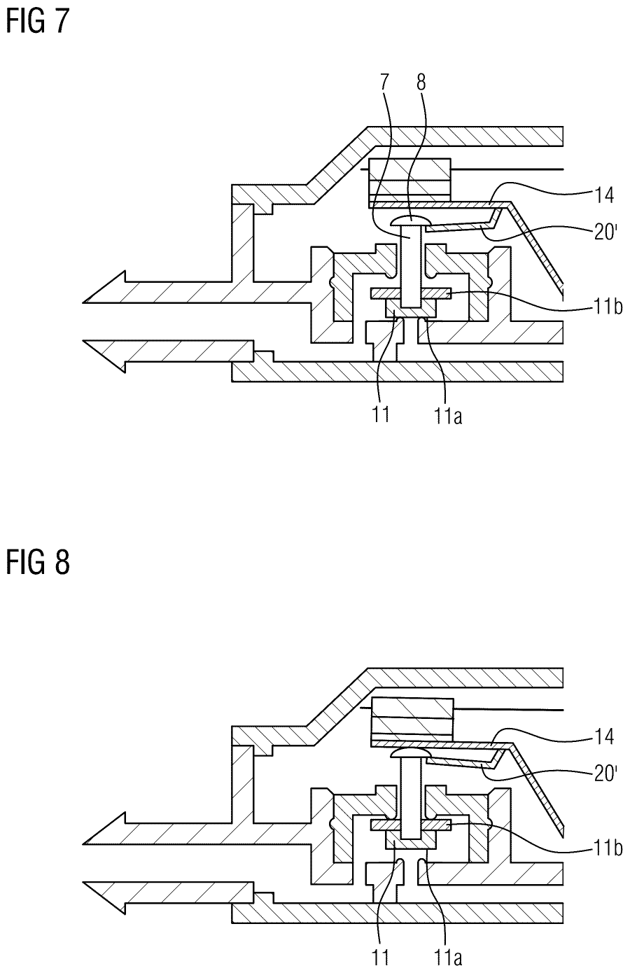

As soon as the SMA actuator 6 is raised at the beginning of the opening process (see FIG. 7), the driver element 20′ exerts an upwardly directed force on the plunger 7, which force intensifies as the stroke increases.

This force is limited to a permissible maximum value by the resilient driver element 20′; said value occurs when the SMA actuator 6 reaches its end position but the plunger 7 is still firmly held in its inoperative position (e.g. by adhesion to the lower nozzle seat).

As soon as the plunger 7 has been released from the lower nozzle seat, it is carried along by the actuator 6 until it bears against the third opening 5. The compressive and tensile forces exerted on the plunger 7 by the actuator 6 cancel one another out in the meantime.

If the plunger 7 has reached its upper position, the valve is completely open (see FIG. 8). The SMA actuator 6 can then move even further into its own end position. In the process, the driver element 20′ then again exerts a (limited) tensile force on the plunger 7, by way of which the latter is pushed against the upper venting nozzle seat of the third opening 5. The venting nozzle can therefore seal even without an inner spring.

The tensile element of the SMA actuator 6 can be integrally formed again in one piece on part of the actuator 6 (e.g. as a tab of an injection molded part or punched and bent part), but can also be mounted in multiple parts, as an additional component, on the actuator 6 and/or plunger 7, e.g., as a clip, which (simultaneously) comes into contact with the plunger from below and the actuating portion of the actuator 6 from above and is fastened captively to one of said two components.

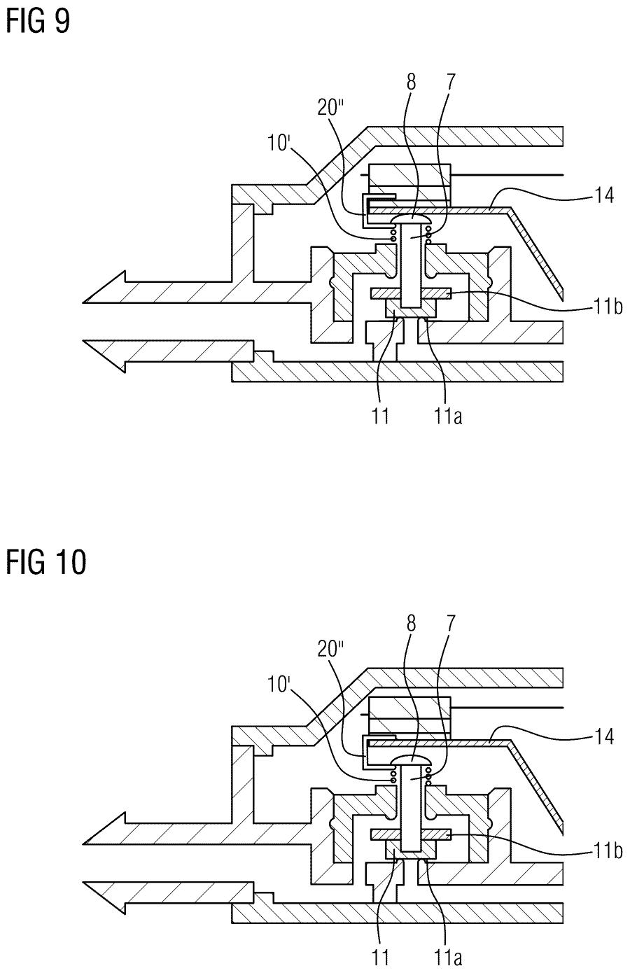

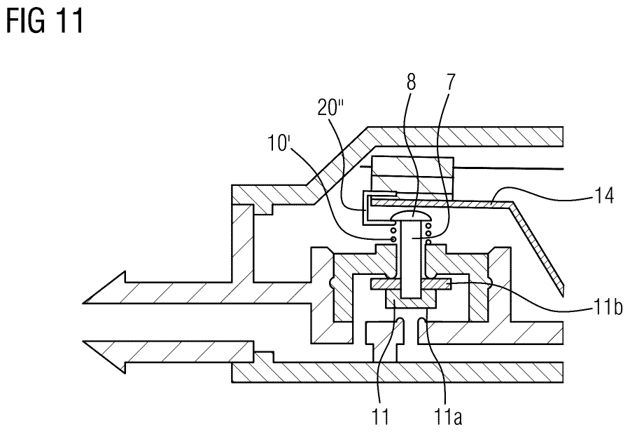

In a third configuration, as is shown in FIGS. 9 to 11, the spring element 10, which is located on the inside, is replaced by a spring element 10′ outside the valve chamber 2. Said spring element bears from below against the widened portion 8 of the plunger 7 and is supported on the upper covering of the valve chamber 2. In the open state of the valve (see FIG. 11), this spring element 10′ holds the plunger 7 in its upper position.

Furthermore, a driver element 20″ is integrally formed as a tab on the spring element 10′ located on the outside, said tab being able to provide an additional force for opening the valve analogously to the driver element 20, 20′ of the first and second embodiments by said driver element 20″ being supported on the actuator 6 (see FIG. 10). The driver element 20″ can also be formed resiliently in order to limit the maximum force on the plunger 7 from the actuator 6.

In the completely open state of the valve, neither the plunger 7 nor the driver element 20″ are in contact with the actuator 6 (see FIG. 11).

In the embodiments mentioned, an increased force for detaching a sticking first sealing element 11a can be applied by the SMA actuator 6 when required, even if the SMA actuator 6 is not located in the pressure chamber.

In this case, the inner spring element 10 in the valve chamber 2 can be configured for a very small force since it only has to move the plunger 7 to the upper end position, but does not serve for detaching a sticking first sealing element 11a. This reduces the force generally to be applied by the SMA actuator 6 and thus increases the service life thereof.

In an alternative embodiment, an inner spring element can be entirely dispensed with since, when the valve is actuated, the actuator 6 exerts a corresponding force upward, which allows the plunger 7 to bear against the upper venting nozzle seat. The maximally acting force can be limited by the force/travel characteristic of the actuator 6 or of the driver element 20′. Therefore, even in the event of error, excessive loading of the SMA actuator is prevented.

In a further embodiment, a spring element 10′ located on the outside replaces the spring element 10 located on the inside and, in addition, is also part of the driver element 20″.

1. A pneumatic valve, comprising a housing in which a valve chamber is arranged with a first opening for connecting to a first housing gas port, a second opening for connecting to a second housing gas port and with a third opening for connecting the valve chamber to an actuator chamber, which is connected to a third housing gas port,
wherein an SMA actuator with a movable closing element is arranged in the housing,
wherein the closing element comprises a plunger which protrudes through the third opening and, at its end projecting into the valve chamber, a sealing plate at which a first sealing element for closing the first opening and a second sealing element for closing the third opening are arranged,
wherein a spring element pushing the second sealing element in a direction of the third opening in an activated state of the pneumatic valve is operatively connected to the closing element,
wherein the plunger and the actuator, via a driver element, have a form-fitting connection with play such that actuation of the actuator causes the plunger to be moved by the actuator to an extent of the play.

2. The pneumatic valve as claimed in claim 1, wherein the driver element is connected fixedly to an actuating portion of the actuator and movably to the plunger in such a manner that it is carried along with the actuating portion when the actuator is actuated and, after reaching the end of the play, carries along the plunger.

3. The pneumatic valve as claimed in claim 1, wherein the spring element comprises a leaf spring on the actuating portion of the actuator which also acts as the driver element.

4. The pneumatic valve as claimed in claim 1, wherein the driver element is connected fixedly to the actuating portion of the actuator.

5. The pneumatic valve as claimed in claim 1, wherein the actuator further comprises:
a printed circuit board arranged in the actuator chamber,
an actuating element arranged in the actuator chamber and having an actuating portion for acting on the plunger, and a bending portion connected to the actuating portion and to the printed circuit board, and
an actuator element arranged in the actuator chamber and having a first end mechanically connected to the actuating portion and a second end mechanically and electrically connected to the printed circuit board,
wherein the actuator element, in a non-energized state, is configured to bring the actuating element into a first state, in which it pushes the plunger against the first opening, and, in an energized state, to bring the actuating element into a second state, in which the actuating portion does not exert any pushing force on the plunger, and therefore, owing to an action of the driver element and the spring element, the second sealing element is pulled or pushed in the direction of the third opening.

6. The pneumatic valve as claimed in claim 5, wherein the driver element is connected fixedly to the actuating portion of the actuator and movably to the plunger in such a manner that it is carried along with the actuating portion when the actuator is actuated and, after reaching the end of the play, carries along the plunger.

7. The pneumatic valve as claimed in claim 5, wherein the driver element is connected fixedly to the actuating portion of the actuator.

8. The pneumatic valve as claimed in claim 5, wherein the spring element comprises a spiral spring in or outside the valve chamber, which spiral spring is supported on a housing part or on an end part and pushes the plunger from the second opening to the third opening.

9. The pneumatic valve as claimed in claim 8, wherein the driver element is connected fixedly to the spring element arranged outside the valve chamber.

10. The pneumatic valve as claimed in claim 8, wherein the driver element is connected fixedly to the actuating portion of the actuator.

11. The pneumatic valve as claimed in claim 5, wherein the spring element comprises a leaf spring on the actuating portion of the actuator which also acts as the driver element.

12. The pneumatic valve as claimed in claim 11, wherein the driver element has a resilient portion, as a result of which, when the actuator is actuated, a variable force is exerted on the plunger.

13. The pneumatic valve as claimed in claim 11, wherein the driver element is connected fixedly to the actuating portion of the actuator and movably to the plunger in such a manner that it is carried along with the actuating portion when the actuator is actuated and, after reaching the end of the play, carries along the plunger.

14. The pneumatic valve as claimed in claim 1, wherein the spring element is comprises a leaf spring on the actuating portion of the actuator which also acts as the driver element.

15. The pneumatic valve as claimed in claim 14, wherein the driver element has a resilient portion, as a result of which, when the actuator is actuated, a variable force is exerted on the plunger.

16. The pneumatic valve as claimed in claim 1, wherein the spring element comprises a spiral spring in or outside the valve chamber, which spiral spring is supported on a housing part or on an end part and pushes the plunger from the second opening to the third opening.

17. The pneumatic valve as claimed in claim 16, wherein the driver element is connected fixedly to the spring element arranged outside the valve chamber.

18. The pneumatic valve as claimed in claim 16, wherein the driver element is connected fixedly to the actuating portion of the actuator.
